(19) United States
(12) Patent Application Publication
(10) Pub. No.: US 2012/0320559 A1
(43) Pub. Date: Dec. 20, 2012

(54) MODULE HAVING ELECTRICAL SHIELD

(75) Inventor: Jun'ichi KIMURA, Osaka (JP)

(73) Assignee: Panasonic Corporation, Osaka (JP)

(21) Appl. No.: 13/587,258

(22) Filed: Aug. 16, 2012

Related U.S. Application Data
(63) Continuation of application No. PCT/JP2011/000940, filed on Feb. 21, 2011.

(30) Foreign Application Priority Data
Mar. 9, 2010 (JP) 2010-051384

(51) Int. Cl. H05K 9/00

(52) U.S. Cl. 361/818

(57) ABSTRACT

A module includes a circuit board, a first and a second circuit block mounted on the top surface of the circuit board, and a first boundary formed between these circuit blocks. The module further includes a first metal piece and a resin part. The first metal piece is mounted on the first boundary. The resin part is provided, on its upper surface, with a first groove in a position corresponding to the first metal piece. The first groove includes a first exposed portion in which the first metal piece is partially exposed from the resin part and is connected to a shielded conductor.

This application is a Continuation of International Application No. PCT/JP11/000,940, filed on Feb. 21, 2011, claiming priority of Japanese Patent Application No. 2010-051384, filed on Mar. 9, 2010, the entire contents of each of which are hereby incorporated by reference.

### TECHNICAL FIELD

The present disclosure relates to a module that includes a plurality of circuit blocks required to be shielded from each other.

### BACKGROUND ART

One example of a conventional module will be described as follows with reference to drawings.

FIG. 8 is a sectional view of the conventional module 101. Conventional module 101 includes circuit board 102, wiring conductors formed on the upper surface of circuit board 102, and electronic components 103a and 103b mounted on the wiring conductors. In module 101, electronic component 103a is included in circuit block 104a, and electronic component 103b is included in circuit block 104b.

Module 101 further includes resin part 105, which is formed on the upper surface of circuit board 102 in such a manner as to encapsulate electronic components 103a and 103b. Resin part 105 has recess 107, which is formed in boundary region 106 between circuit blocks 104a and 104b. Recess 107 penetrates resin part 105, and the bottom surface of recess 107 reaches a position deeper than the upper surface of circuit board 102.

Circuit board 102 is provided with ground conductors 108 on its upper surface and its inside. Ground conductors 108 are formed along the outer periphery of the circuit board and boundary region 106, and are exposed in an exposed portion of resin part 105.

Module 101 further includes shielding conductor 109 on the upper and entire side surfaces of resin part 105, the side surfaces of circuit board 102, and the inner surface of recess 107. Shielding conductor 109, which are formed by sputtering, are connected to ground conductors 108 in the exposed portion.

This structure allows each circuit in circuit blocks 104a and 104b to be shielded, and also allows circuit blocks 104a and 104b to be shielded from each other.

Circuit board 102 has a smaller thickness in boundary region 106 due to the presence of recess 107 and tends to get warped. To avoid this, recess 107 is filled with resin 105a so as to increase the strength of circuit board 102.

In conventional module 101, however, shielding conductor 109 need to be connected to the ground conductors 108 formed along boundary region 106 in order to shield circuit blocks 104a and 104b from each other. To achieve this, recess 107 penetrates resin part 105 and has a depth enough to reach circuit board 102. To form shielding conductor 109 uniformly on resin part 105 and throughout the inner circumference surface of recess 107 by sputtering or other methods, recess 107 needs to have width 107a not less than the depth of recess 107. In addition to the large width 107a of recess 107, the ground conductor 108 formed along boundary region 106 needs to have width 108a larger than width 107a of recess 107. To ensure the space for mounting electronic components 103a and 103b, module 101 is large in size.

### SUMMARY

The present disclosure provides a compact module that includes a plurality of circuit blocks required to be shielded individually. The compactness is achieved by arranging the circuit blocks close to each other by minimizing the space unsuitable for mounting electronic components near the boundaries between the circuit blocks.

In the present disclosure, a metal piece is mounted on the boundary, and a groove may be formed at a position corresponding to at least the metal piece on the upper surface of a resin part. The groove includes an exposed portion in which the metal piece is partially exposed from the resin part and is connected to shielding conductor.

The module of the present disclosure includes a circuit board, a plurality of electronic components, a resin part, and shielding conductor. The electronic components are mounted on the circuit board. The resin part is formed on the upper surface of the circuit board in such a manner as to cover the electronic components. The shielding conductor is formed on the upper and side surfaces of the resin part. In the module, a first circuit block is formed on the upper surface of the circuit board; a second circuit block is formed adjacent to the first circuit block on the circuit board; a first boundary is formed between the first and second circuit blocks on the upper surface of the circuit board. In addition, a first metal piece is mounted on the first boundary; and a first groove is formed at a position corresponding to at least the first metal piece on the upper surface of the resin part. The first groove includes a first exposed portion in which the first metal piece is partially exposed from the resin part and is connected to the shielding conductor.

In the above structure, since the metal piece is mounted on the boundary, and the groove is formed in the position corresponding to the metal piece, the groove can be small in depth and width, making the distance between the first and second circuit blocks small. As a result, the module of the present disclosure can be compact.

### BRIEF DESCRIPTION OF DRAWINGS

FIG. 1A is a sectional view of a module according to a first exemplary embodiment of the present disclosure.

FIG. 1B is a top view of the module according to the first exemplary embodiment of the present disclosure.

FIG. 2 is an overhead sectional view of the module according to the first exemplary embodiment of the present disclosure

FIG. 3A is a top view of an example of another metal piece of the module according to the first exemplary embodiment of the present disclosure.

FIG. 3B is a top view of an example of still another metal piece of the module according to the first exemplary embodiment of the present disclosure.

FIG. 3C is a side view of the metal piece of FIG. 3B.

FIG. 4A is an overhead sectional view of a module using yet another metal piece according to the first exemplary embodiment of the present disclosure.

FIG. 4B is a top view of the module using yet another metal piece according to the first exemplary embodiment of the present disclosure.

FIG. 5A is a sectional view of a module having boundary formed in T shape according to the first exemplary embodiment of the present disclosure.

FIG. 5B is a top view of the module having boundary formed in T shape according to the first exemplary embodiment of the present disclosure.

FIG. 6A is a sectional view of a module having boundary formed in L shape according to the first exemplary embodiment of the present disclosure.

FIG. 6B is a top view of the module having boundary formed in L shape according to the first exemplary embodiment of the present disclosure.

FIG. 7 is a flowchart of manufacturing the module according to the first exemplary embodiment of the present disclosure.

FIG. 8 is a sectional view of a conventional module.

### DESCRIPTION OF EMBODIMENT

The following is a description, with reference to drawings, of a module 21 according to a first exemplary embodiment.

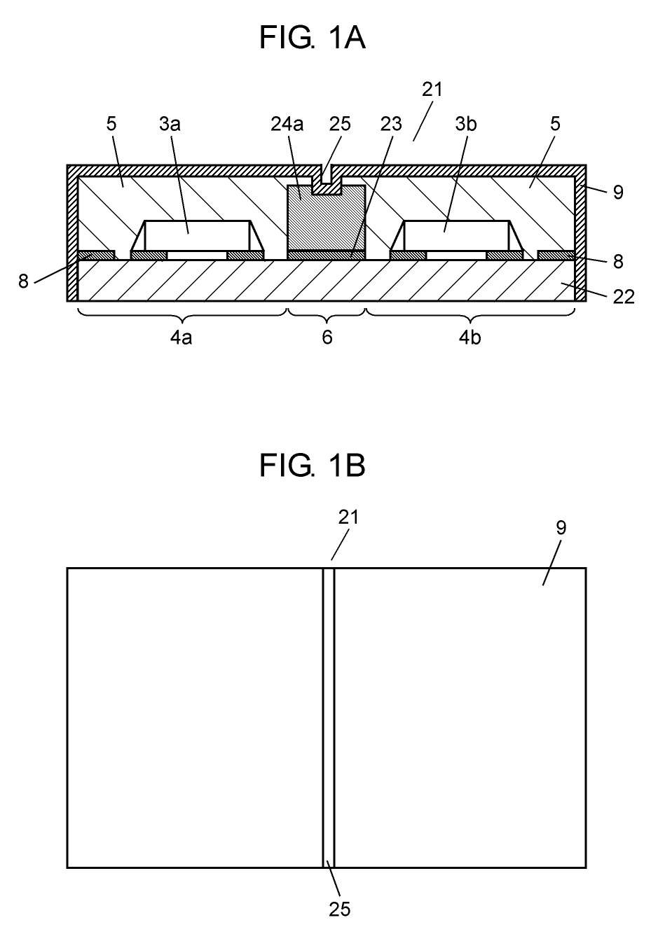

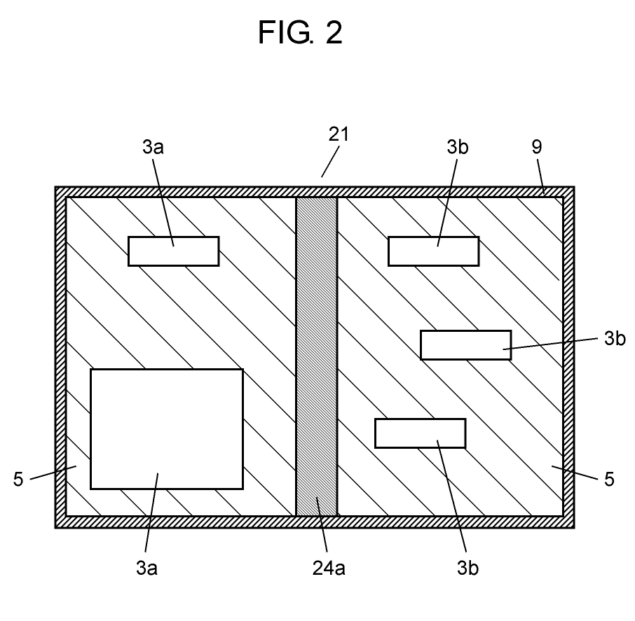

FIG. 1A is a sectional view of a module 21 according to a first exemplary embodiment of the present disclosure. FIG. 1B is a top view of the module 21 according to the first exemplary embodiment of the present disclosure. FIG. 2 is an overhead sectional view of the module 21 according to the first exemplary embodiment of the present disclosure.

As shown in FIGS. 1A, 1B and 2, the module 21 includes circuit board 22, wiring conductors formed on the upper surface of circuit board 22, and electronic components 3a and 3b mounted on certain positions of the wiring conductors. On circuit board 22, electronic components 3a form first circuit block 4a, and electronic components 3b form second circuit block 4b. In the present exemplary embodiment, first circuit block 4a includes an electronic tuner circuit, and second circuit block 4b includes a modulator circuit.

On the upper surface of circuit board 22, first circuit block 4a and second circuit block 4b are separated from each other by first boundary 6. The module 21 further includes ground conductor 23, which extends, in first boundary 6, in the longitudinal direction of circuit board 22 on its upper surface. The module 21 further includes first metal piece 24a on ground conductor 23. First circuit block 4a and second circuit block 4b are connected to each other via signal wiring conductors (not shown) formed inside circuit board 22. The module 21 preferably includes another ground conductor 8 in a position of circuit board 22 that is opposite to ground conductor 23, sandwiching the signal wiring conductors between ground conductors 23 and 8.

First metal piece 24a has a length substantially the same as the width of circuit board 22. In other words, first metal piece 24a is formed in first boundary 6 in such a manner as to longitudinally extend from one end to the other of circuit board 22. This arrangement of first metal piece 24a ensures electrical separation between first circuit block 4a and second circuit block 4b. First metal piece 24a may be shorter than the width of circuit board 22. In that such a case, first metal piece 24a is prevented from projecting from the circuit board 22 even if mounted out of alignment.

On the upper surface of circuit board 22, the module 21 further includes resin part 5 where electronic components 3a and 3b and first metal piece 24a are embedded. Resin part 5 includes first groove 25 in a position corresponding to first metal piece 24a. First groove 25 penetrates the resin over first metal piece 24a. First metal piece 24a is partially exposed on the bottom surface of first groove 25, thereby forming a first exposed portion.

Ground conductors 8 and 23 are formed on the upper surface and inside circuit board 22. Ground conductor 8 is formed along the outer periphery of the board, and is exposed from resin part 5 or the side surfaces of circuit board 22. Ground conductor 23 is connected to first metal piece 24a.

The module 21 further includes shielding conductor 9 on the upper and entire side surfaces of resin part 5, the side surfaces of circuit board 22, and the inner surface of first groove 25. Shielding conductor 9 is connected to the exposed portion of ground conductor 8 on the side surfaces of circuit board 22. Shielding conductor 9 is also connected to first metal piece 24a in the first exposed portion. This structure allows respective circuits in first circuit block 4a and second circuit block 4b to be shielded, and also allows first circuit block 4a and second circuit block 4b to be electrically shielded from each other.

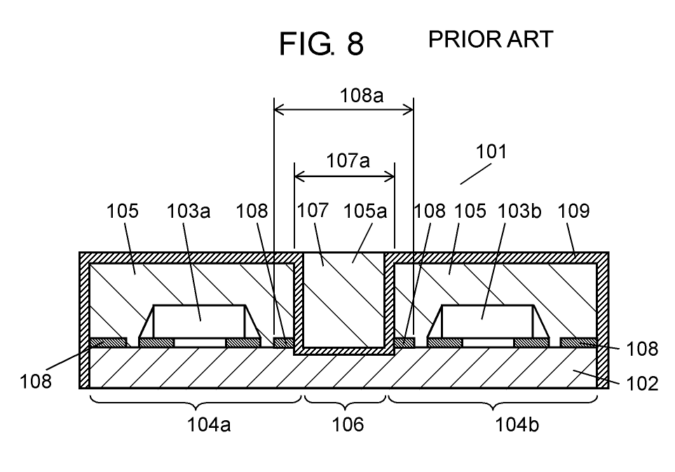

In the first exemplary embodiment of the present disclosure, first metal piece 24a is formed in first boundary 6 in such a manner as to longitudinally extend from one end to the other of circuit board 22. Because first metal piece 24a exists, unlike the conventional module of FIG. 8, first groove 25 may be shallow and narrow. This minimizes the space unsuitable for mounting electronic components 3a and 3b due to the presence of first boundary 6, so that first circuit block 4a and second circuit block 4b can be arranged close to each other. As a result, the module 21 of the present disclosure can be compact.

In the present exemplary embodiment, first metal piece 24a has the same length as the width of circuit board 22. Therefore, both ends of first metal piece 24a are exposed from resin part 5 and connected to shielding conductor 9. This further ensures the shielding of each circuit in first circuit block 4a and second circuit block 4b.

As formed by sputtering, shielding conductor 9 is very dense films having an excellent shielding effect.

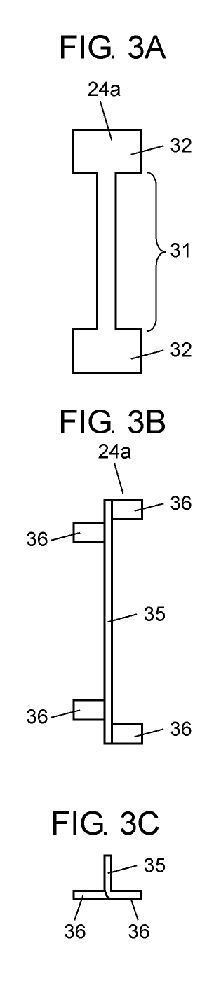

FIG. 3A is a top view of an example of another metal piece of the module 21 according to the first exemplary embodiment of the present disclosure.

In FIG. 3A, first metal piece 24a includes small-width part 31, and attachment parts 32 having a larger width than small-width part 31. First metal piece 24a is connected to ground conductor 23 via attachment parts 32.

Forming attachment parts 32 at both ends of first metal piece 24a stabilizes the mounting arrangement. At least one attachment part 32 is provided to stabilize the mounting arrangement, depending on the shape of first circuit block 4a and second circuit block 4b. Also, the positions of attachment parts 32 and small-width part 31 may be changed depending on the shape of first circuit block 4a and second circuit block 4b.

Forming small-width part 31 allows electronic components 3a and 3b to be mounted near first boundary 6, thereby efficiently using circuit board 22. As a result, module 21 of the present disclosure can be further compact.

When the width of small-width part 31 is too small, the width of first groove 25 is preferably larger than the width of small-width part 31. This ensures the exposure of first metal piece 24a even if first groove 25 is formed out of alignment, or first metal piece 24a is mounted out of alignment.

FIG. 3B is a top view of an example of still another metal piece of the module 21 according to the first exemplary embodiment of the present disclosure.

FIG. 3C is a side view of the metal piece of FIG. 3B. In FIGS. 3B and 3C, first metal piece 24a is formed by bending a steel sheet. First metal piece 24a includes partition 35 and attachment parts 36. Partition 35 is placed in first boundary 6, and attachment parts 36 are formed by being bent at partition 35.

First metal piece 24a, which is thus formed by bending a steel sheet, minimizes the space unsuitable for mounting electronic components 3a and 3b. As a result, module 21 of the present disclosure can be compact.

Attachment parts 36 provided on both sides of partition 35 prevent first metal piece 24a from falling or tilting while being mounted on circuit board 22. This allows electronic components 3a and 3b to be mounted near partition 35, improving the utilization of circuit board 22.

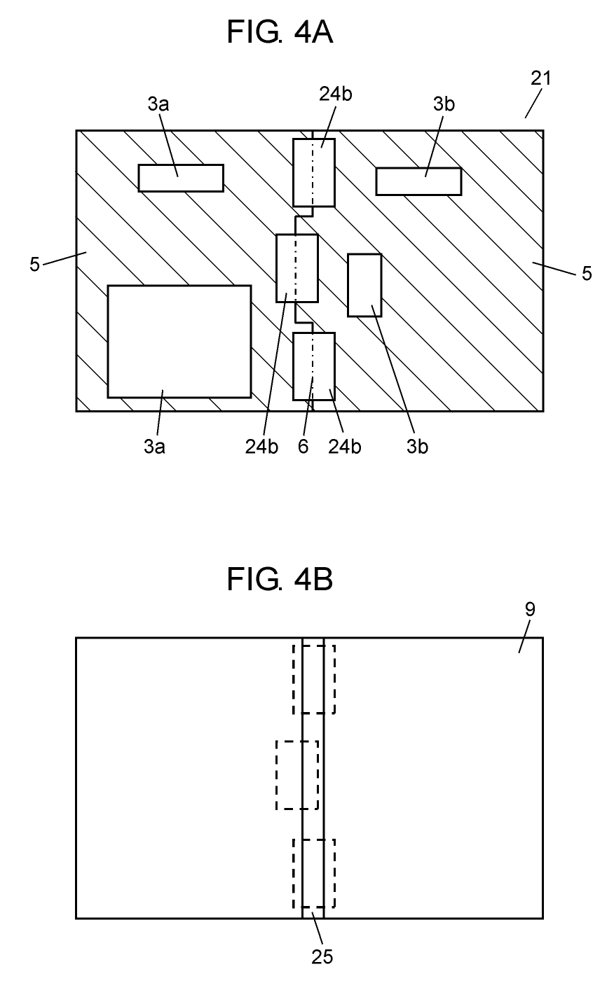

FIG. 4A is an overhead sectional view of a module 21 and FIG. 4B is a top view of the module 21, using yet another metal piece according to the first exemplary embodiment of the present disclosure. In FIGS. 4A and 4B, module 21 includes first metal pieces 24b mounted along first boundary 6. First metal pieces 24b are short quadratic prisms (like chip parts).

As shaped like chip parts, first metal pieces 24b can be mounted by a general mounting machine, thereby improving the productivity of the module 21 of the present disclosure. First metal pieces 24b can also be mounted out of alignment so as to be partially exposed from first groove 25. This facilitates the shielding between first circuit block 4a and second circuit block 4b along first boundary 6 even if boundary 6 has a rough surface.

The spaces between adjacent first metal pieces 24b can be used to connect the circuits in first circuit block 4a and second circuit block 4b. More specifically, on the upper surface of circuit board 22, since these spaces can be used for signal wiring conductors, it is not necessary to provide a multilayer board for connecting first circuit block 4a and second circuit block 4b. As a result, module 21 of the present disclosure can be inexpensive. In FIGS. 4A and 4B, three first metal pieces 24b are mounted on circuit board 22, but their number can be determined differently depending on the size of the width of circuit board 22 or the shape of first boundary 6.

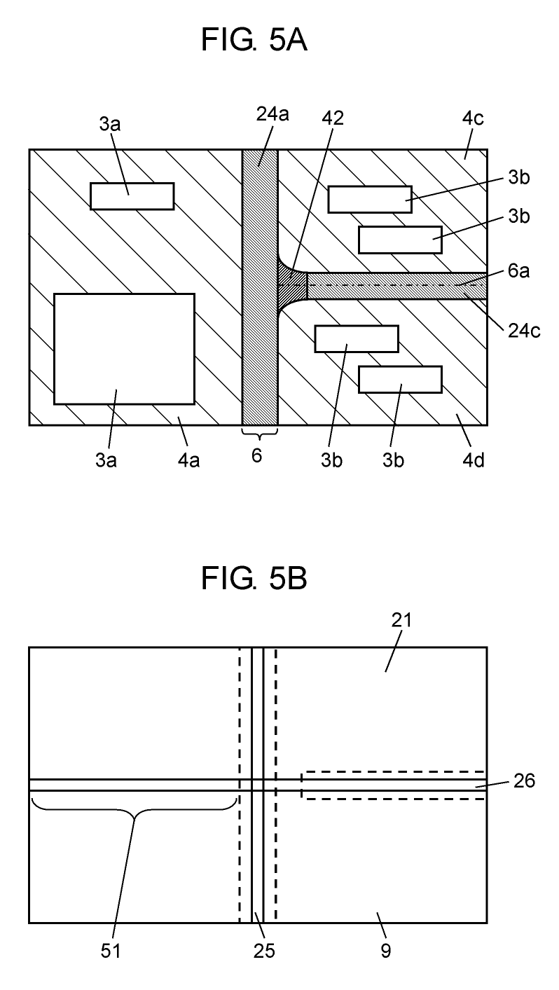

FIG. 5A is a sectional view and FIG. 5B is a top view of a module 21 having boundary formed in a T shape according to the first exemplary embodiment of the present disclosure. As shown in FIGS. 5A and 5B, module 21 includes third and fourth circuit blocks 4c and 4d, which are separated from first circuit block 4a by first boundary 6. First metal piece 24a is mounted in first boundary 6. Third circuit block 4c and fourth circuit block 4d are separated from each other by second boundary 6a. First and second boundaries 6 and 6a together form a T shape. In first boundary 6 and second boundary 6a, there are mounted first metal piece 24a and second metal piece 24c, respectively. First groove 25 and second groove 26 are arranged crisscross to expose first metal piece 24a and second metal piece 24c, respectively.

Second groove 26 is formed at a position corresponding to at least second metal piece 24c on the upper surface of resin part 5. Second groove 26 penetrates the resin over second metal piece 24c. Second metal piece 24c is partially exposed on the bottom surface of second groove 26, thereby forming a second exposed portion. Second groove 26 is provided with shielding conductor 9, which is connected to second metal piece 24c in the second exposed portion.

This structure allows first circuit block 4a, third circuit block 4c and fourth circuit block 4d to be shielded from each other.

Second groove 26 extends in the lateral direction of module 21 up to the region not including second metal piece 24c (the region in an extension of second boundary 6a) on the upper surface of resin part 5. Second groove 26, however, can be as shallow as to let second metal piece 24c be exposed. As a result, electronic components 3a can be mounted in a region under second groove 26.

When arranged in a T shape, first metal piece 24a and second metal piece 24c are spaced from each other, so that first metal piece 24a and second metal piece 24c can be prevented from hitting each other if mounted out of alignment. The space between first metal piece 24a and second metal piece 24c is about as large as the maximum allowable misalignment; in general mounting machines, it is set to about 0.15 mm. The space is filled with cream solder 42 so as to ensure the shielding.

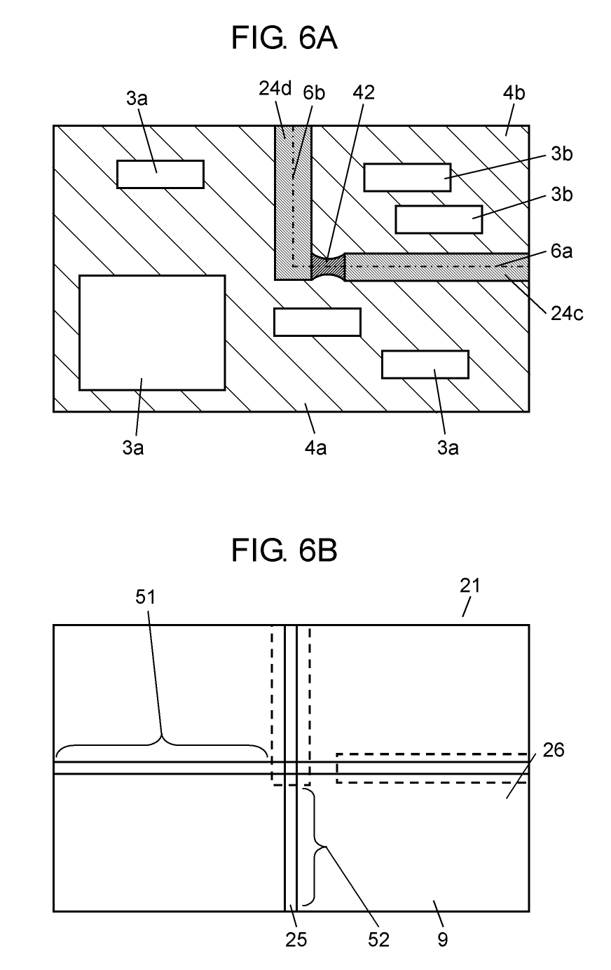

FIG. 6A is a sectional view and FIG. 6B is a top view of a module 21 having boundary formed in an L shape according to the first exemplary embodiment of the present disclosure.

As shown in FIGS. 6A and 6B, first circuit block 4a and second circuit block 4b are separated from each other by second boundary 6a and third boundary 6b, which together form an L shape. The module 21 further includes third metal piece 24d. Second metal piece 24c and third metal piece 24d are mounted on second boundary 6a and third boundary 6b, respectively. First groove 25 and second groove 26 are arranged crisscross to expose third metal piece 24d and second metal piece 24c, respectively. The upper surface of resin part 5 includes regions 51 and 52 (the regions in extensions of second boundary 6a and third boundary 6b, respectively). The second groove 26 extends up to region 51 not including second metal piece 24c, and first groove 25 extends up to region 52 not including third metal piece 24d. Second groove 26 and first groove 25, however, can be as shallow as to let second metal piece 24c and third metal piece 24d, respectively, be exposed. As a result, electronic components 3a can be mounted under regions 51 and 52, thereby maintaining the mounting space.

Instead of an L shape, second boundary 6a and third boundary 6b may alternatively form a U shape or a rectangular shape. It is possible to shield circuit blocks of various shapes or arrangements by combining boundaries and metal pieces.

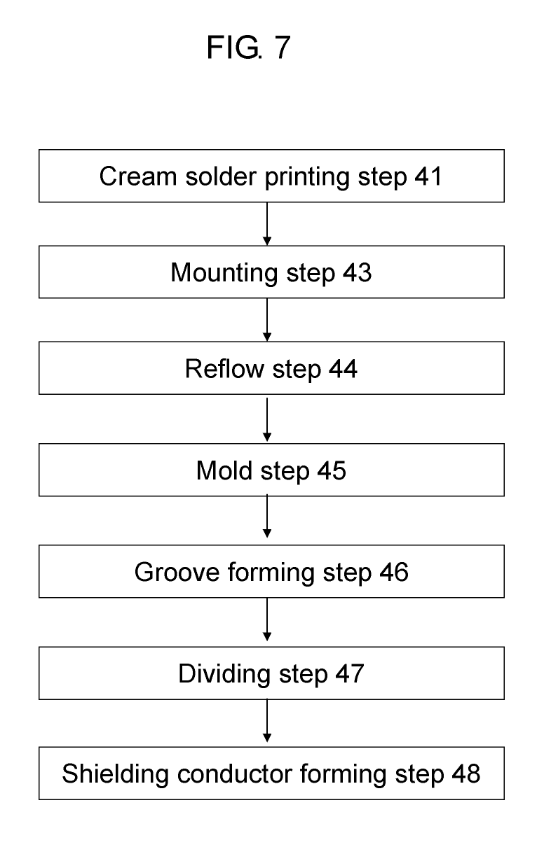

FIG. 7 is a flowchart of manufacturing the module 21 (shown in FIGS. 1A, 1B, and 2) according to the first exemplary embodiment. As shown in FIG. 7, connection substrate consists of a plurality of circuit boards 22, which are arranged at regular intervals and connected by joints. The following is a description, with reference to FIG. 7, of the manufacture of the module 21 of the present disclosure.

First, in cream solder printing step 41, cream solder is applied to the upper surface of connection substrate via a metal mask. In this case, cream solder is applied to the positions where electronic components 3a and 3b are to be mounted or ground conductor 23 is already formed.

Next, in mounting step 43, electronic components 3a and 3b are mounted on certain positions on the upper surface of circuit board 22, and first metal piece 24a is also mounted on ground conductor 23. First metal piece 24a, which has a length larger than the width of circuit board 22, is mounted so that both ends can project from the outer periphery of circuit board 22.

In mounting step 43, first metal piece 24b, second metal piece 24c, and third metal piece 24d are mounted on circuit board 22 in the same manner as first metal piece 24a.

Next, in reflow step 44, cream solder is heat-melted, and then cooled to be solidified, so that electronic components 3a and 3b, and first metal piece 24a are connected and fixed on circuit board 22.

Next, in mold step 45, resin part 5 is formed on the upper surface of connection substrate (on the side where electronic components 3a and 3b, and first metal piece 24a have been mounted). In the present exemplary embodiment, a cavity is disposed on connection substrate using a transfer resin molding die. Then, molten resin 5a is poured into the cavity and solidified. As a result of this step, resin part 5 in which electronic components 3a and 3b, and first metal piece 24a have been embedded is formed on the upper surface of circuit board 22. In this case, first metal piece 24a should be completely filled with resin 5a.

Next, in groove forming step 46, first groove 25 is formed on the upper surface of resin part 5. More specifically, first groove 25 is formed in a position of resin part 5 that corresponds to first metal piece 24a using a dicing saw, thereby exposing first metal piece 24a from resin part 5. As a result of this step, first metal piece 24a is exposed at the bottom of first groove 25 of resin part 5. First groove 25 extends in the longitudinal direction of circuit board 22 from one end to the other.

When a plurality of metal pieces are arranged at right angles to each other such as first metal piece 24a and second metal piece 24c, or second metal piece 24c and third metal piece 24d, first groove 25 and second groove 26 are arranged crisscross. In this case, too, first groove 25 and second groove 26 extend in the longitudinal and lateral directions, respectively, of circuit board 22.

Next, in dividing step 47, circuit board 22 is separated from the other circuit boards, and resin part 5 is separated from the other resin parts by cutting thorough the joints using a dicing saw. As a result, ground conductor 8 is exposed from the side surfaces of circuit board 22. Both ends of first metal piece 24a, which project from the outer periphery of circuit board 22 in the present exemplary embodiment, are also cut in this dividing step 47 and are exposed from the side surfaces of resin part 5.

Finally, in shielding conductor forming step 48, shielding conductor 9 is formed on the upper and side surfaces of resin part 5 and the side surfaces of circuit board 22. Shielding conductor 9 is also formed on the exposed portion of first metal piece 24a on the bottom of first groove 25; on the exposed portion of ground conductor 8 on the side surfaces of circuit board 22; and at both ends of first metal piece 24a exposed on the side surfaces of resin part 5. Then, shielding conductor 9 is connected to first metal piece 24a and ground conductor 8.

This is the completion of module 21 in which first circuit block 4a and second circuit block 4b are shielded from each other. First circuit block 4a and second circuit block 4b are each fully electrically shielded, surrounded by ground conductor 23, first metal piece 24a, and shielding conductor 9.

Even when first circuit block 4a or second circuit block 4b includes a high-frequency circuit, this shielding effect can reduce the electrical interference between different circuits, allowing first circuit block 4a and second circuit block 4b to be arranged close to each other. As a result, module 21 can be compact. Because formed by sputtering in the present exemplary embodiment, shielding conductor 9 has high density, thereby providing high shielding performance.

In the present exemplary embodiment, first metal piece 24a, second metal piece 24c, and third metal piece 24d are mounted in such a manner that both ends project from the outer periphery of circuit board 22. Then, both ends are cut in dividing step 47, thereby exposing their cut ends from resin part 5. It is alternatively possible that first metal piece 24a, second metal piece 24c, and third metal piece 24d are not long enough to let both ends project from the outer periphery of circuit board 22. In this case, their both ends are not cut in dividing step 47, allowing extending the life of the dicing saw and also preventing metal burrs from occurring on the exterior of module 21. The absence of metal burrs is important to prevent a short circuit between module 21 and an electronic component adjacent to module 21 while module 21 is being mounted on a motherboard.

Conversely, first metal pieces 24b may be mounted in such a manner as to project from circuit board 22. By doing so, first metal pieces 24b can be connected to shielding conductor 9 even on the side surfaces of resin part 5, thereby further improving shielding performance. The spaces between adjacent first metal pieces 24b are preferably reduced by being filled with cream solder 42, thereby further improving the shielding performance.

### INDUSTRIAL APPLICABILITY

The compact module of the present disclosure is useful as a high-frequency module including a plurality of high-frequency circuit blocks.

### REFERENCE MARKS IN THE DRAWINGS

3a, 3b electronic component
4a first circuit block
4b second circuit block
4c third circuit block
4d fourth circuit block
5 resin part
6 first boundary
6a second boundary
6b third boundary
9 shielding conductor
22 circuit board
23 ground conductor
24a, 24b first metal piece
24c second metal piece
24d third metal piece
25 first groove
26 second groove

1. A module comprising:
a circuit board;
a first circuit block including at least one first electronic component and disposed on an upper surface of the circuit board;
a second circuit block including at least one second electronic component and disposed, adjacent to the first circuit block, on the upper surface of the circuit board;
a first metal piece disposed on the upper surface of the circuit board and dividing the first circuit block and the second circuit block;
a resin part disposed on the upper surface of the circuit board covering at least the first and second circuit blocks; and
a shielding conductor disposed on an upper surface and a side surface of the resin part, wherein:
a first groove is disposed at a position of an upper surface of the resin part above the first metal piece, and
the first groove includes a first exposed portion in which the first metal piece is at least partially exposed from the resin part, and the first metal piece is connected to the shielding conductor at the first exposed portion.

2. The module of claim 1,
wherein the first groove extends straight from one side to another side of the resin part.

3. The module of claim 2,
wherein a height from the upper surface of the circuit board to a bottom of the first groove is larger than a height of the first and second electronic components.

4. The module of claim 3,
wherein the first metal piece includes two metal pieces arranged in an L shape.

5. The module of claim 1, wherein:
the second circuit block is divided into a third circuit block and a fourth circuit block adjacent to the third circuit block,
a second metal piece is disposed on the upper surface of the circuit board between the third and fourth circuit blocks,
the first circuit block, the third circuit block, and the fourth circuit block are arranged in such a manner that the first metal piece and the second metal piece together form a T shape,
a second groove is disposed at a position of the upper surface of the resin part above the second metal piece, and
the second groove includes a second exposed portion in which the second metal piece is at least partially exposed from the resin part, and the second metal piece is connected to the shielded conductor at the second exposed portion.

6. The module of claim 1,
wherein at least one end of the first metal piece is exposed from the resin part and connected to the shielding conductor.

7. The module of claim 1, further comprising:
a ground conductor disposed on the circuit board, wherein:
the first metal piece includes a small-width part and an attachment part,
the attachment part has a larger width than small-width part, and
the first metal piece is connected to the ground conductor via the attachment parts.

8. The module of claim 1, wherein the first metal piece includes one or more quadratic prisms.

9. The module of claim 1, the module further comprising:
a second metal disposed on the upper surface of the circuit board; and
a second groove disposed at a position of the upper surface of the resin part corresponding to at least the second metal piece,
wherein the second groove extends up to the region not including the second metal piece.

10. A module comprising:
a circuit board;
a first circuit block including at least one first electronic component and formed on an upper surface of the circuit board;
a second circuit block including at least one second electronic component and formed, adjacent to the first circuit block, on the upper surface of the circuit board;
a first metal piece disposed on the upper surface of the circuit between the first and second circuit blocks, and having a height higher than heights of the first and second electronic components;
a resin part formed on the upper surface of the circuit board; and
a shielding conductor formed on an upper surface and a side surface of the resin part,
wherein the first metal piece partially exposes from the resin part to form an exposed portion and connects to the shielding conductor at the exposed portion.

11. The module of claim 10, wherein:
the shielding conductor and the first metal piece contacts so as to divide a shield space formed by the shielding conductor into two shielding spaces, and
the first and second circuit blocks are disposed in the two shielding spaces, respectively.

12. The module of claim 10,
wherein at least one end of the first metal piece is exposed from the resin part and connected to the shielding conductor.

13. The module of claim 10, further comprising:
a ground conductor disposed on the circuit board, wherein:
the first metal piece includes a small-width part and an attachment part,
the attachment part has a larger width than small-width part, and
the first metal piece is connected to the ground conductor via the attachment parts.

14. The module of claim 10,
wherein the first metal piece includes one or more quadratic prisms.

15. The module of claim 10, further comprising:
a second metal disposed on the upper surface of the circuit board; and
a second groove disposed at a position of the upper surface of the resin part corresponding to at least the second metal piece,
wherein the second groove extends up to the region not including the second metal piece.
